(19) United States
(12) Patent Application Publication
(10) Pub. No.: US 2013/0040547 A1
(43) Pub. Date: Feb. 14, 2013

(54) DATA CENTER COOLING

(71) Applicant: David A. Moore, Tomball, TX (US)

(72) Inventor: David A. Moore, Tomball, TX (US)

(73) Assignee: Hewlet-Packard Developement Company, L.P., Houston, TX (US)

(21) Appl. No.: 13/641,214

(22) PCT Filed: May 20, 2010
(86) PCT No.: PCT/US10/35598

§ 371 Date: Oct. 15, 2012

(51) Int. Cl. H05K 5/02

(52) U.S. Cl. 454/184

(57) ABSTRACT

A data center includes a building having a pitched roof. The building includes a ventilation gallery extending a length of the building. The ventilation gallery is formed at a peak of the pitched roof and includes vertical louvered walls. The data center includes an equipment gallery structurally supporting the ventilation gallery and including exterior vertical walls forming the length and a width of the building. A series of electrical equipment is mounted in equipment racks in the equipment gallery arranged in two rows forming a common aisle between the two rows. The electrical equipment includes coaling inlets oriented toward the exterior vertical walls and exhaust outlets oriented toward the common aisle. Aisle separators extend vertically from the equipment racks to the ventilation gallery.

### BACKGROUND

Energy used to power and cool electronic equipment in today's typical data centers significantly contributes to the total cost of data center operation. Moreover, in an example state of the art data center a third to half of total energy usage is for cooling the electronic equipment. Traditionally, data center thermal control has included closed loop thermal control using chillers or refrigeration to cool a fixed volume of recirculating air. A substantial portion of this energy usage is for closed loop recirculating air cooling systems which utilize either direct expansion or chilled water air conditioning units.

One recent type of data center cooling is referred to as air side economizer, which induces cooler exterior air into the data center to augment the traditional computer room air conditioner (CRAC) cooling. Air side economizers partially employ reduced exterior temperatures, but the air side economizer data center design is otherwise not significantly changed as compared to a traditional CRAC data center design. Typical air side economizer facilities retain the traditional flat roofed, low ceiling box structure typical of closed loop facilities and thus are not able to fully take advantage of the cooler exterior air.

For these and other reasons, a need exists for the present invention.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate corresponding similar parts.

FIG. 1 is a cross-sectional view of a data center according to one embodiment.

FIG. 2 is a plan view of an equipment gallery of a data center according to one embodiment

FIG. 3 is a flow diagram of a process of cooling a data canter according to one embodiment.

### DETAILED DESCRIPTION

In the following detailed description, reference is made to the accompanying drawings which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present Invention is defined by the appended claims.

It is to be understood that the features of the various exemplary embodiments described herein may be combined with each other, unless specifically noted otherwise.

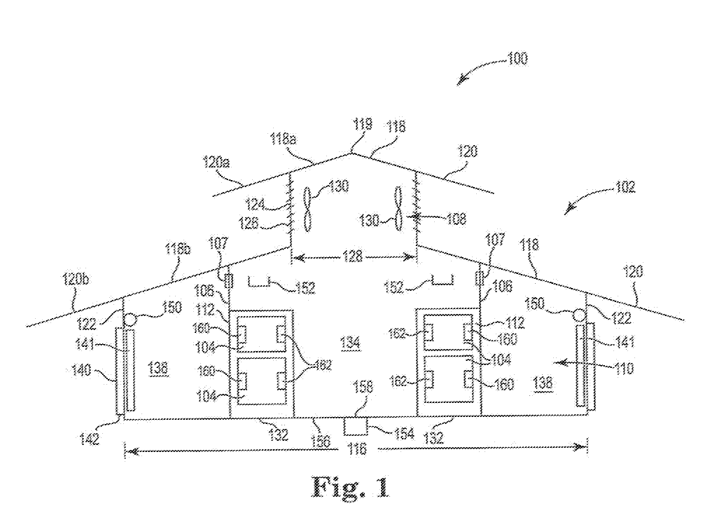

FIG. 1 is a cross-sectional view of a data center 100 according to one embodiment. Data center 100 Includes a building 102, and electrical equipment 104 and aisle separators 108 within building 102. Building 102 includes a ventilation gallery 108 and an equipment gallery 110. Electrical equipment 104 is mounted in equipment racks 112 arranged in equipment gallery 110. Aisle separators 108 extend vertically from equipment racks 112 to ventilation gallery 108.

In one embodiment, building 102 is a modular metal building. Other suitable building materials can be used in building 102, such as concrete and wood. In one embodiment, building 102 is a pre-fabricated structure. In one embodiment, building 102 is constructed onsite at a selected location.

In one embodiment, roof 118 of building 102 is pitched or sloped. In one embodiment, roof 118 has a substantial eave 120 overhang, generally following the slope of the roof 118 along terminate edges of each roof level. In one embodiment, eave 120 extends several feet beyond the building 102 footprint. In the illustrated embodiment, roof 118 has two levels including a lower roof 118b above equipment gallery 110 and an upper roof 118a above ventilation gallery 108. In this manner, roof 118a is elevated and separated from lower roof 118b.

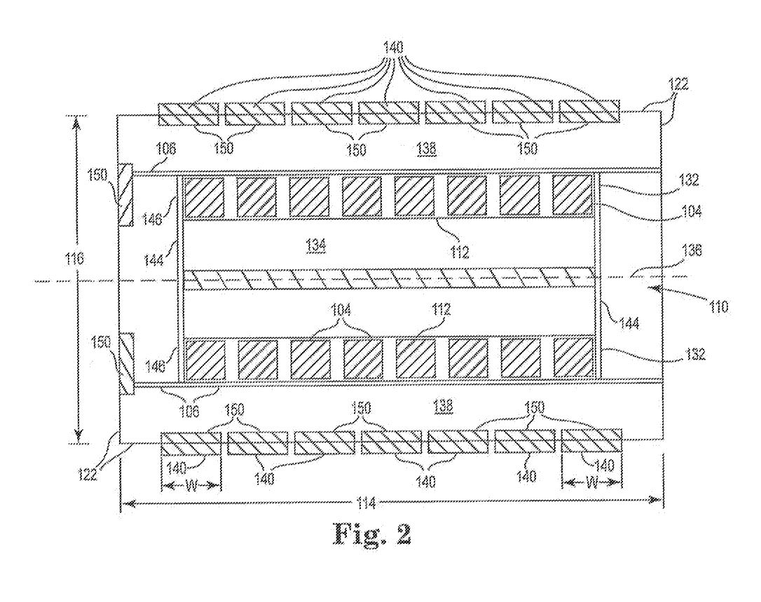

In one embodiment, eaves 120b extend lower roof 118b beyond perimeter walls 122 of equipment gallery 110. Similarly, in one embodiment, eaves 120a extend upper roof 118a beyond upper wails 124. In one embodiment, eaves 120a and 120b extend along a building length (indicated by arrows 114 in FIG. 2) on opposing sides of building 102. In one embodiment, eaves 120a and 120b provide protection from exterior weather elements and prevent precipitation water from entering building 102.

In one embodiment, roof 118 is constructed of a self supporting material such as deep corrugated metal. Roof 118 can be constructed of other suitable roofing materials, such as asphalt shingles with supporting structure.

Ventilation gallery 108 extends above equipment gallery 110 and is formed along peak 119 of roof 118. In one embodiment, ventilation gallery 108 and equipment gallery 110 are openingly connected on the interior. In one embodiment, ventilation gallery 108 extends the building length (indicated by arrows 114 in FIG. 2) of building 102 and is undivided.

In one embodiment, exterior walls 124 of ventilation gallery 108 extend vertically from roof 118b of equipment gallery 110 to roof 118a of ventilation gallery 108. In one embodiment, walls 124 of ventilation gallery 108 are louvered or include louvers 126, which provide passage of air from the interior to the exterior of building 102. In one embodiment, louvers 128 are assembled in a series along the length indicated by arrows 114 of wails 124. In one embodiment, louvers 126 are only included on opposing walls 124 which are positioned under overhanging extended eaves 120. In another embodiment, louvers 126 are included on all of walls 124 of ventilation gallery 108. The louvers 126 can be fixed or adjustable, or a combination thereof.

In one embodiment, ventilation gallery 108 includes one or more circulation fan 130. Circulation fans 130 assist in air movement through equipment gallery 110 and ventilation gallery 108. In one embodiment each circulation fan 130 is mounted along opposing walls 124. In another embodiment, circulation fan 130 is mounted horizontally along the bottom of the ventilation gallery 108 to force air upward from the equipment gallery 110.

In one embodiment, circulation fan 130 includes a variable speed drive system. In one embodiment, the speed of circulation fan 130 is controlled with a fan controller based on measurements of the environmental factors, such as temperature, at the electrical equipment 104. The quantity, size, position, and type of circulation fans 130 employed in ventilation gallery 108, can be determined by such design factors, far example, as the size of building 102, the type and amount of electrical equipment 104, the power generated by electrical equipment 104, the fans included in electrical equipment 104, and the environment in which building 102 is to be located. For example, in one embodiment, circulation fans 130 are supplemental to fans already included in electrical equipment 104 and can increase airflow through building 102.

In one embodiment, circulation fans 130 provide airflow through the electrical equipment 104, minimizing or eliminating the use of fans within the electrical equipment 104. In another example, large circulation fans 130 may be used in order to reduce the number of circulation fans 130 and/or fans within the electrical equipment 104. In one embodiment, circulation fans 130 assist in balancing the interior pressure of building 102 and pressure drops which may occur in the airflow between filters 140 and louvers 128.

FIG. 2 is a plan view of equipment gallery 110 or data center 100 according to one embodiment. In one embodiment, building 102 is a long, narrow structure wherein a building length, indicated by arrows 114, exceeds a building width, indicated by arrows 116. The building length, indicated by arrows 114, is a suitable length to achieve the desired equipment capacity. In one embodiment, a length of 118 of ventilation gallery 108 is the same as a length of equipment gallery 110, as such indicated by arrows 114. In one embodiment, a width indicated by arrows 116, of equipment gallery 110 is greater than a width indicated by arrows 128 in FIG. 1, of ventilation gallery 108.

Equipment gallery 110 is constructed and configured to accommodate electrical equipment 104. In one embodiment, a series of electrical equipment 104, such as servers, disk drive arrays, network switching equipment, and other electrical end data equipment, are mounted in equipment racks 112 arranged in equipment rows 132. In one embodiment, equipment racks 112 are cabinets. In one embodiment, equipment racks 112 are arranged in two equipment rows 132 forming a common aisle 134 between the two rows 132. In one embodiment, equipment rows 132 are substantially parallel; however, equipment rows 132 may be any suitable configuration which creates a common aisle 134 between the rows 132.

In one embodiment, coding inlets 180 of heat generating electrical equipment 104 are oriented toward exterior perimeter wails 122 to receive cooler air from one of exterior aisles 138. In one embodiment, exhaust outlets 162 of heat generating equipment 104 are oriented toward common aisle 134 to exhaust warmer air into common aisle 134. In one embodiment, common aisle 134 extends along a central long axis 136 of building 102. In one embodiment, common aisle 134 is centered below ventilation gallery 108 to allow natural convection forces to lift the warm exhausted air up and out of building 102. This natural convection air flow is supplemented by the fans installed in electrical equipment 104, which move air from the cool exterior aisles 138 to the warm common aisle 134, and also by circulation fans 130. In one embodiment, the combined action of the natural convection forces, fans in electrical equipment 104, and circulation fans 130 creates a positive airflow circulation through building 102, without re-circulation of air.

In one embodiment, aisle separators 106 extend from equipment racks 112 to ventilation gallery 108. In one embodiment, aisle separators 106 provide a seal between the tops of equipment racks 112 and roof 118b. In one embodiment, aisle separators 106 form a suspended system, supported from the roof structure of roof 118b. In one embodiment., aisle separators 106 are configured to deflect and channel heated air generated by operating electrical equipment 104 into common aisle 134. In one embodiment, aisle separators 106 prevent recirculation of heated air from common aisle 134 back into the cooling inlets 160 of electrical equipment 104. This can also allow differential pressure created by fans in equipment 104 to augment the airflow circulation through building 102 created by natural convection. In another embodiment, variable opening recirculation dampers 107 are incorporated into aisle separators 106 to allow controlled internal recirculation of air from the common aisle 134 to the exterior aisles 138.

In one embodiment, additional sealing walls 144 are installed at ends 146 of equipment rows 132 to prevent recirculation around the end 146 of rows 132. In another embodiment, aisle separators 106 are configured along the length indicated by arrows 114 of the equipment gallery 110 to abut opposing exterior walls 122. In one embodiment, aisle separators extend to floor 156 in areas where electrical equipment 104 is absent.

In one embodiment, aisle separators 108 are a standard wall construction of suitable materials, such as metal or wood framing and drywall. Embodiments of aisle separators 106 can also be constructed of other suitable materials such as plexi-glass and sheet metal. In one embodiment, aisle separators 106 are panelized sections which can be adjusted, removed, and replaced. In one embodiment, aisle separators 106 are constructed as a continuous length. In one embodiment, the angle and position of aisle separators 106 is fixed. In another embodiment, the angle, position and/or length of aisle separators 106 is adjustable.

In one embodiment, one or more air filters 140 are configured to filter and remove particles and/or gaseous contamination from exterior air from entering aisle 138 and are mounted at exterior perimeter walls 122. In one embodiment, air filters 140 are filter boxes having a box structure. In one embodiment, a series of air filters 140 are mounted along the building length indicated by arrows 114 on opposing sides of building 102. In one embodiment, air filters 140 are mounted at base 142 of vertical perimeter walls 122.

In one embodiment, air filters 140 comprise a roll feed filter media solution attached to supporting framework which can provide for longer maintenance intervals. In one embodiment air filters 140 are divided into segments of reasonable length (e.g., approximately 10 feet). Segmentation of air filters 140 can allow service to one of the air filters 140 segments without interrupting the operation of data center 100. In one embodiment, air filters 140 constructed as box segments provide filter redundancy, because the open space between air filters 140 and electrical equipment 104 allows for mixing of exterior air. For example, in one embodiment, electrical equipment 104 in data center 100 continues operation even if one segment of air filters 140 is completely blocked during operation.

In one embodiment, air filters 140 are configured to provide particulate removal from the outside air as the air enters, or before the air enters, building 102. In one embodiment, air filters 140 are configured to mitigate gaseous and particulate contamination of electrical equipment 104. In one embodiment, air filters 140 remove large particulate from the cool exterior air as the exterior air enters equipment gallery 110. In one embodiment, air filters 140 removes extremely fine particulate from the cool exterior air as the exterior air enters equipment gallery 110. In one embodiment, the type of filtration provided by air filters 140 is selected based on the type of electrical equipment 104 being supported in data center 100.

In one embodiment, building 102 includes one or more overhead door 150 configured to close off air filters 140 from equipment gallery 110. In one embodiment, building 102 includes additional overhead doors 150 to allow equipment and personal access into and out of different data center areas of building 102. In one embodiment, at least one overhead door 150 is a rolling overhead door. In another embodiment, at least one overhead door 150 is a sectional overhead door. Each overhead door 150 can be manually and/or electro-mechanically operated. In one embodiment, each overhead door 150 has similar dimensions as air filters 140, (e.g., each overhead door 150 and each filtration 150 have W wide openings where W is a suitable opening width, such as 10 feet). Each overhead door 150 forms a sealable opening at each of filtrations 140 along perimeter walls 122, thereby preventing air flow through the corresponding filtration 140 segment when closed. In one embodiment, overhead door 150 is positioned at the interior side of air filters 140. The ability to shut off airflow through a selected air filters 140 segment facilitates maintenance of the filter media without the risk of particulate ingress. Thus, in one embodiment, a selected air filters 140 segment is removed and replaced while a corresponding overhead door 150 is temporarily closed. In one embodiment, the corresponding overhead deer 150 is reopened after the selected air filters 140 segment has been replaced.

In one embodiment, each overhead door 150 prevents particulate material trapped on the filter media from entering building 102 when closed, along with particulate material present in the outside air. Air from adjacent air filters 140 segments supply filtered cool air to the intake cooling inlets 160 of equipment 104 adjacent to the selected air filters 140 segment being serviced. Closing off one selected air filter 140 segment at a time can provide uninterrupted operation of data center 100. The combination of air filters 140 and overhead doors 150 provide redundancy for filtration of the air in building 102, because the air is free to mix in the un-divided cool exterior aisle 138 air space.

In one embodiment equipment gallery 110 includes one or more wiring chase 152. In one embodiment, each wiring chase 152 is suspended inside equipment gallery 110 from roof 118. Each wiring chase 152 provides convenient access to network cables and other electrical wiring.

In one embodiment, equipment gallery 110 includes one or more power troughs 154. In one embodiment, each power trough 154 extends along each equipment row 132. In one embodiment, each power trough 154 is recessed in floor 156 of building 102. In one embodiment each power trough 154 includes a removable cover 158 to provide an even surface over the power trough on floor 156. In one embodiment, each power trough 154 facilitates separate routing of electrical power lines to electrical equipment 104. In one embodiment, the electrical power lines are routed on floor 156 with a suitable covering to prevent personnel from tripping on the lines.

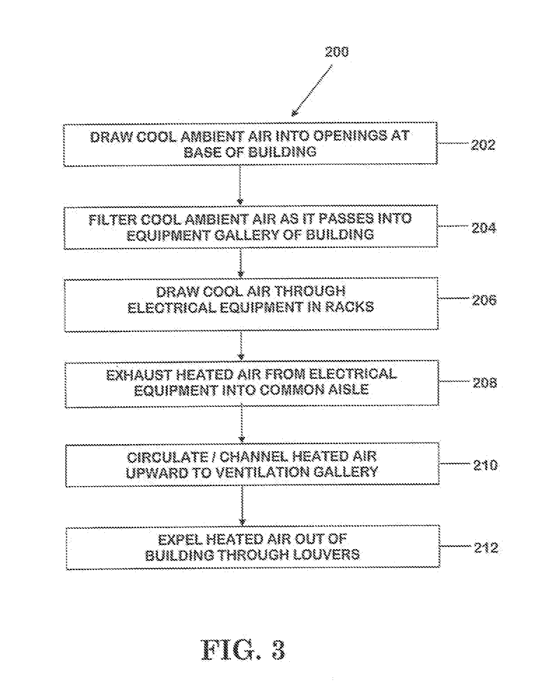

FIG. 3 illustrates one embodiment of a process 200 of cooling data center 100. At 202, cool exterior ambient air is drawn into openings at base 142 of building 102. At 204, cool exterior ambient air is filtered as it passes into equipment gallery 110 of building 102. At 206, cool air is drawn through electrical equipment 104 in racks 112. At 208, heated air is exhausted from operating electrical equipment 104 into common aisle 134. At 210, the heated air is circulated and channeled upward to ventilation gallery 108 of building 102. At 212, the heated air is expelled from the building 102 through louvers 126 in exterior walls 124 of ventilation gallery 108.

The natural buoyancy of warm air heated by operation of electrical equipment 104, coupled with the fans installed in electrical equipment 104 and/or circulation fans 130, creates an upward flow from common aisle 134 between equipment racks 112. The upward flow of warm air exits ventilation gallery 108 through louvers 126, thus removing heat from data center 100. The open design of building 102 facilitates air mixing along central axis 138 of building 102. The warm air exiting the upper ventilation gallery 108 of building 102 continues to rise outside of building 102, and does not tend to mix with the cool air entering building 102. In one embodiment, extended eaves 120 are configured and positioned to reduce or prevent the exiting warm air from reentering building 102. The physical separation provided by extended eaves 120 reduces or prevents the air exiting from recirculating and raising the intake temperature of incoming cool air at base 142 of building 102.

Exterior weather variations (e.g., variations in temperature, humidity, wind, rain, snow, sun, etc.) at data center 100 locations can mean that, at least some of the time, exterior temperatures are sufficiently low to allow external air to be employed directly to cool electrical equipment 104. In order for this to be practical, relatively large volumes of air are moved through data center 100. Exclusive employment of exterior air may not be sufficient for cooling at all times. As such, supplementary cooling systems can be employed and installed in data center 100. For example, in some geographical locations, supplemental cooling is employed in periods of high external temperatures. In one embodiment, evaporative coolers 141 are employed to reduce the temperature of air entering data center 100 through air filters 140 during periods of high external temperatures and/or low external humidity. Alternatively, In periods of low external temperatures, recirculation dampers 107 within aisle separators 106 allow internal circulation of the equipment heated air in common aisle 134 to exterior aisles 139 within data center 100. Additionally, during periods of low temperatures, circulation fans 130 are operated at a low speed and/or louvers 126 are at least partially closed.

Embodiments of free air cooled data center facilities which cool entirely with external ambient air can be built without installing a cooling tower, chiller, chilled water circulating system, or computer room air conditioners (CRACs). Embodiments can substantially reduce capital equipment as well as operating costs. Significant reductions in electrical usage with embodiments over traditional “chiller plant” designs have substantial advantages for companies desiring to reduce their green house gas emissions. Electrical usage reductions also equate to lower recurring costs for operation.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

1. A data center, comprising:
a building including:
a pitched roof;
an equipment gallery includes exterior vertical walls forming a length and a width of the building; and
a ventilation gallery disposed above the equipment gallery and extending the length of the building, wherein the ventilation gallery is formed at a peak of the pitched roof and includes vertical louvered walls;
a series of electrical equipment mounted in equipment racks in the equipment gallery arranged in two rows forming a common aisle between the two rows, wherein the electrical equipment includes cooling inlets oriented toward the exterior vertical walls and exhaust outlets oriented toward the common aisle; and
aisle separators extending vertically from the equipment racks to the ventilation gallery.

2. The data center of claim 1 comprising:
at least one air filter mounted at the exterior vertical walls.

3. The data center of claim 2 comprising:
at least one overhead door positioned and sized to provide a sealable opening at each of the at least one air filter.

4. The data center of claim 1 comprising:
at least one circulation fan mounted within the ventilation gallery.

5. The data center of claim 1, wherein the building comprises a steel frame structure and enclosure.

6. The data center of claim 1, wherein the common aisle is substantially centered below the ventilation gallery.

7. The data center of claim 1 comprising:
at least one wiring chase suspended from the pitched roof.

8. The data center of claim 1 comprising:
at least one power trough recessed in a floor of the building.

9. A method of cooling a data center, the method comprising:
arranging electrical equipment in equipment racks in two rows forming a common aisle between the two rows;
circulating warmed air generated by the electrical equipment into the common aisle and upward through a center portion of the building to a ventilation gallery;
exhausting the warmed air out through louvered wall openings in the ventilation gallery; and
intaking external air through exterior openings positioned at a base of the building structure, wherein the external air is cooler than the exhausted warmed air.

10. The method of claim 9 comprising:
preventing the warmed air from, reentering the building with extended eaves of a sloped roof on the building.

11. The method of claim 9 comprising:
filtering the external air through filters disposed at the exterior openings at the base of the building structure.

12. The method of claim 11 comprising:
closing an overhead door positioned at an interior side of one of the filters;
removing and replacing replaceable parts of the air filter; and
reopening the overhead door.

13. A data center, comprising:
a building including:
an equipment gallery having at least one exterior wall opening sealable with an overhead door; and
a ventilation gallery having exterior vented louvered walls, the ventilation gallery centered along a peak in a sloped roof above the equipment gallery,
wherein the equipment gallery and the ventilation gallery have a vertically open connecting interior, and a width of the equipment gallery is greater than a width of the ventilation gallery;
a filter included on an exterior side of the overhead door at the at least one exterior wall openings; and
electrical equipment mounted in rows of equipment racks within the equipment gallery forming a common aisle between the rows.

14. The data center of claim 13 comprising:
a wall separator between tops of the equipment racks and the roof.

15. The data center of claim 13, wherein the sloped roof includes overhanging eaves extending beyond the exterior walls of both the ventilation gallery and the equipment gallery along a length of the building.
